(19) United States
(12) Patent Application Publication
(10) Pub. No.: US 2025/0388177 A1
(43) Pub. Date: Dec. 25, 2025

(54) DEVICE BODY MOUNTING STRUCTURE

(71) Applicant: JVCKENWOOD Corporation, Yokohama-shi (JP)

(72) Inventor: Azrie AHMAD, Yokohama-shi (JP)

(21) Appl. No.: 19/309,944

(22) Filed: Aug. 26, 2025

Related U.S. Application Data
(63) Continuation of application No. PCT/JP2023/047167, filed on Dec. 28, 2023.

(30) Foreign Application Priority Data
Mar. 3, 2023 (JP) 2023-032547

(51) Int. Cl. B60R 11/00

(52) U.S. Cl. CPC B60R 11/00; B60R 2011/0043

(57) ABSTRACT

A device body mounting structure includes a frame and a device body. The frame includes a frame wall part. The device body includes a first wall part and a second wall part. The device body includes a restricting member disposed on the first wall part, and an insertion port formed on the device body on a user side and configured such that a tool can be inserted. The restricting member is formed with: an engaging part disposed on the first wall part, and protruding toward the frame wall part and configured to be engaged with the frame wall part; and a releasing part disposed along the second wall part and connected to the engaging part. The releasing part includes a part configured to be pressed by the tool in a direction away from the frame wall part when the tool is inserted through the insertion port.

### CROSS-REFERENCE TO RELATED APPLICATIONS

The present application is a continuation of International Application No. PCT/JP2023/047167 filed on Dec. 28, 2023, and based upon and claims the benefit of priority from Japanese Patent Application No. 2023-032547 filed on Mar. 3, 2023, the entire contents of which are incorporated herein by reference.

### TECHNICAL FIELD

The present invention relates to a device body mounting structure.

### BACKGROUND

An apparatus for detachably mounting audio equipment disclosed in Patent Literature 1 (JP 11-28985 A) includes: a mounting frame having engagement apertures formed on both sides; and a main chassis provided with an opening part and a latch member. The apparatus includes engagement members which are engaged with corresponding engagement apertures when the main chassis is mounted on the mounting frame, and are disengaged from the engagement apertures when the main chassis is separated from the mounting frame. The apparatus includes a frame fixed to the front side of the main chassis and having insertion holes corresponding to the engagement apertures formed on both sides, and disengagement members which disengage the engagement members from the engagement apertures, and engage with the latch member of the main chassis in such a manner that the main chassis is pulled along forward.

In device body mounting structures, there is a case where a device body is fixed to a frame. In such a case, the device body is fixed to the frame by engaging a protruding part, which is formed to protrude from a side part of the frame covering a body part of the device body toward the device body, with a predetermined position on a side part of the body part, for example. When removing the device body from the frame, the engagement between the protruding part and the side part of the device body is released by inserting a removing tool between the protruding part and the side part of the device body. However, due to the structure of a front part formed on a user side of the device body, there is a case where it is difficult to form an insertion port for inserting the removing tool, in the front part. Therefore, there are cases where it is difficult to remove the device body from the frame with the conventional device body mounting structure.

### SUMMARY

A device body mounting structure according to the present embodiment includes: a frame disposed in a recessed space opened to a user side; and a device body configured to be mounted to the frame, wherein the frame includes: a frame wall part configured to cover at least part of the device body, the device body includes: a first wall part configuring one side of the device body in one of a width direction and a height direction; a second wall part configuring one side of the device body in the other of the width direction and the height direction; a restricting member disposed on the first wall part and configured to restrict movement of the device body with respect to the frame; and an insertion port formed on the device body on the user side and configured such that a tool for removing the device body from the frame can be inserted therein, the restricting member is formed with: an engaging part disposed on the first wall part, and protruding toward the frame wall part and configured to be engaged with the frame wall part; and a releasing part disposed along the second wall part and connected to the plurality of engaging parts, the releasing part includes a part configured to be pressed by the tool in a direction away from the frame wall part when the tool is inserted through the insertion port.

### BRIEF DESCRIPTION OF THE DRAWINGS

FIG. 1 is a diagram illustrating a frame and a device body of a device body mounting structure according to an embodiment, and a perspective view of a state where the device body is removed from the frame.

FIG. 2 is a diagram illustrating the frame and the device body of the device body mounting structure according to the embodiment, and a perspective view of a state where the device body is mounted to the frame.

FIG. 3 is an enlarged view illustrating the main part of the device body mounting structure according to the embodiment, and a perspective view illustrating a disposition relationship between a body part of the device body, a front part, and a restricting member.

FIG. 4 is a perspective view illustrating the restricting member of the device body mounting structure according to the embodiment.

FIG. 5 is a side view illustrating the restricting member of the device body mounting structure according to the embodiment, as viewed from the device right.

FIG. 6 is a front view illustrating the restricting member of the device body mounting structure according to the embodiment, as viewed from the device front.

FIG. 7 is an enlarged view illustrating the main part of the device body mounting structure according to the embodiment, and is a schematic cross-sectional view taken along the line VII-VII of FIG. 2, for explaining a state where an engaging part is engaged with a frame wall part.

FIG. 8 is an enlarged view illustrating the main part of the device body mounting structure according to the embodiment, and is a schematic cross-sectional view corresponding to FIG. 7, for explaining a disposition relationship between a tool, the restricting member, and the frame wall part in a state where the tool is inserted into an insertion port.

FIG. 9 is an enlarged view illustrating the main part of the device body mounting structure according to the embodiment, and is a schematic cross-sectional view corresponding to FIG. 7, for explaining the disposition relationship between the tool, the restricting member, and the frame wall part in a state where the tool is inserted further into the insertion port than in the state illustrated in FIG. 8.

FIG. 10 is an enlarged view illustrating the main part of the device body mounting structure according to the embodiment, and is a schematic cross-sectional view corresponding to FIG. 7, for explaining the disposition relationship between the tool, the restricting member, and the frame wall part in a state where the tool is inserted further into the insertion port than in the state illustrated in FIG. 9.

FIG. 11 is a side view corresponding to FIG. 5, illustrating the restricting member of the device body mounting structure according to a modification of the embodiment, as viewed from the device right side.

### DETAILED DESCRIPTION

A device body mounting structure according to an embodiment will be described below with reference to the drawings. Note that the following description concerns a case where the device body mounting structure according to the embodiment is applied to a vehicle cabin, but the device body mounting structure according to the embodiment is not limited to the vehicle cabin and can be applied to objects other than the vehicle cabin. When the device body mounting structure is applied to the vehicle cabin, the device body is also called on-board device.

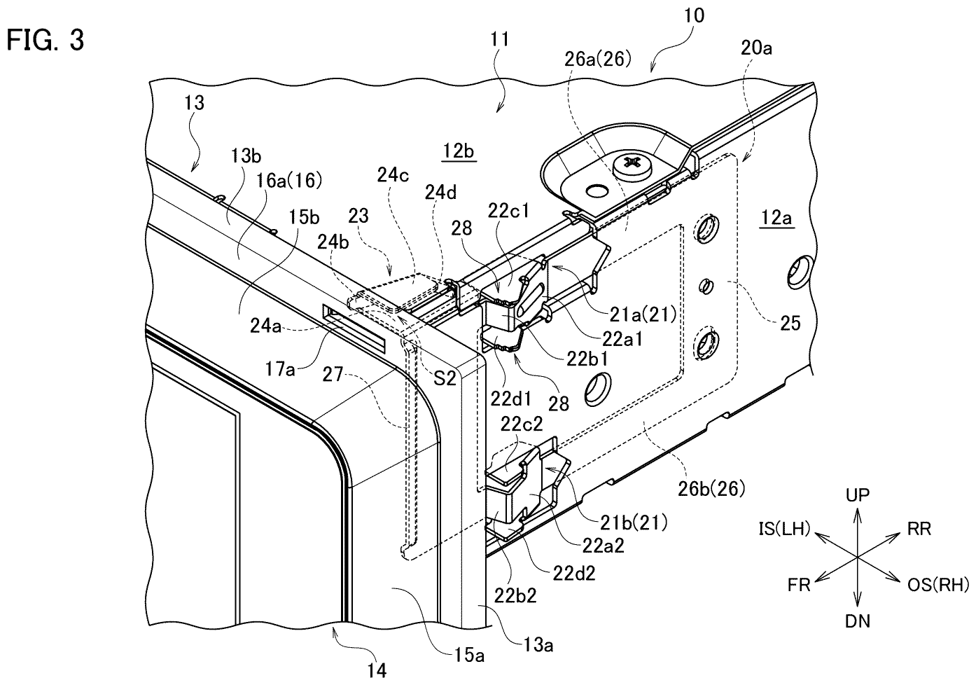

In each figure, FR and RR indicate the front and the rear of the device body in the longitudinal direction, respectively. LH and RH indicate the left and the right of the device body in the width direction, respectively. UP and DN indicate the up and the down of the device body in the vertical direction, respectively. A direction facing the center of the device body in the width direction is referred to as “inward in a device width direction”, and a direction opposite to the inward in the device width direction is referred to as “outward in a device width direction”. In the following description, the front and rear of the device body in the longitudinal direction, the left and right of the device body in the width direction, and the upper and lower sides of the device body in the vertical direction are referred to simply as “device front”, “device rear”, “device left”, “device right”, “device upper side”, and “device lower side”, respectively. Elements having the same function are denoted by the same reference numerals, and duplicate descriptions are omitted. Note that in examples illustrated in FIGS. 3 to 11, the inward in the device width direction is indicated by IS, and the outward in the device width direction is indicated by OS.

Note that the front of the device body in the longitudinal direction is a direction facing the vehicle cabin when the device body is disposed in a predetermined position in the vehicle cabin. The rear of the device body in the longitudinal direction is a direction facing opposite to the front of the device body in the longitudinal direction. In the following description, the depth direction of a device body 10 corresponds to a device longitudinal direction. The height direction of the device body 10 corresponds to the device vertical direction. The width direction of a frame 1 and the width direction of a body part 11 correspond to the device width direction. The height direction of the frame 1 and the height direction of the body part 11 correspond to the device height direction. Note that in some cases, the width direction of the device body 10 is simply referred to as “width direction”, and the height direction of the device body 10 is simply referred to as “height direction”.

The device body mounting structure can be applied when the device body 10 is disposed at a predetermined position in the vehicle cabin, for example. The type and function of the device body 10 are not particularly limited. The device body 10 may be, for example, a car audio or a car navigation system to be mounted on an instrument panel (not illustrated) of a vehicle.

The device body mounting structure includes the frame 1 and the device body 10.

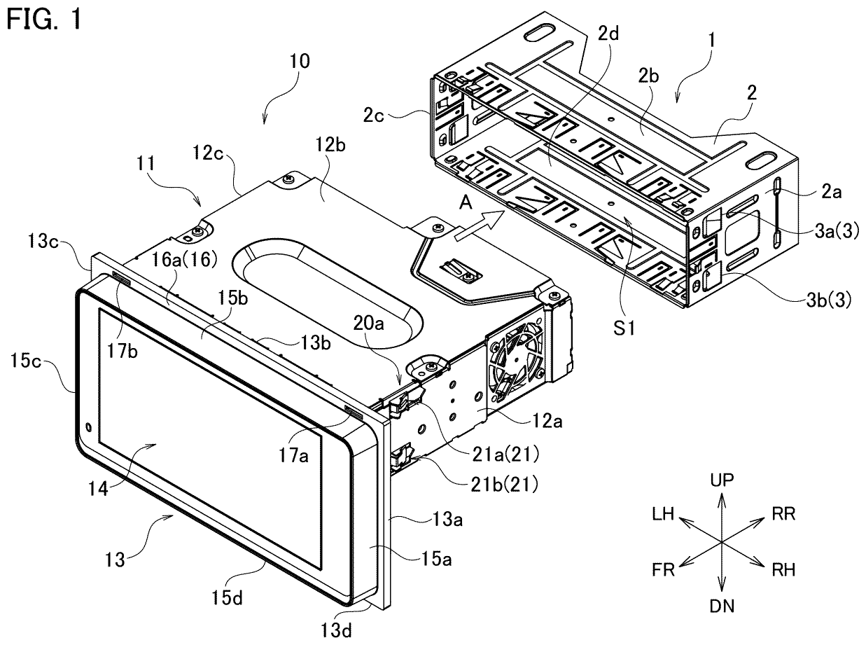

The frame 1 is a member where the device body 10 is mounted. The frame 1 is disposed in a recessed space (not illustrated) opening toward the vehicle cabin. Thus, the recessed space is opened toward the side of a user who uses the device body 10. The recessed space is defined by a recessed part (not illustrated) formed in a vehicle interior member at a predetermined position. For example, the recessed space is formed in the recessed part by recessing the instrument panel at a predetermined position toward the inside. In a removed state described below, the recessed space communicates with a space in the vehicle cabin. Note that, for example, the frame 1 may be disposed in the recessed space formed in the instrument panel at the predetermined position, through a fastener (not illustrated), such as a bracket. The frame 1 exemplified in FIG. 1 is a tubular member having a substantially rectangular shape when viewed in the device longitudinal direction and extending in the device longitudinal direction, and is made from, for example, a metal, such as aluminum or stainless steel. In the illustrated example, the dimension of the frame 1 in the width direction is set larger than that in the height direction but is not limited thereto. The shape and configuration of the frame 1 may be appropriately set according to, for example, the shape of the body part 11 of the device body 10, which will be described below.

The frame 1 includes a frame wall part 2 that covers at least part of the device body 10. In the example illustrated in FIG. 1, the frame wall part 2 includes a frame wall part 2a, a frame wall part 2b, a frame wall part 2c, and a frame wall part 2d. Noe that the configuration of the frame wall part 2 is not limited to the illustrated example. For example, the frame wall part 2 need not include any of the frame wall parts 2a, 2b, 2c, or 2d.

The frame wall part 2a configures the right side of the frame 1. The frame wall part 2b configures the upper side of the frame 1. The frame wall part 2c configures the left side of the frame 1. The frame wall part 2d configures the lower side of the frame 1. Note that in the examples illustrated in each figure, the front of the frame 1 corresponds to the device front, and the rear of the frame 1 corresponds to the device rear. The right of the frame 1 corresponds to the device right, and the left of the frame 1 corresponds to the device left. The upper side of the frame 1 corresponds to the device upper side, and the lower side of the frame 1 corresponds to the device lower side. Note that the frame wall parts 2a and 2c are also called frame side walls. The frame wall part 2b is also called an upper frame wall part. The frame wall part 2d is also called a lower frame wall part.

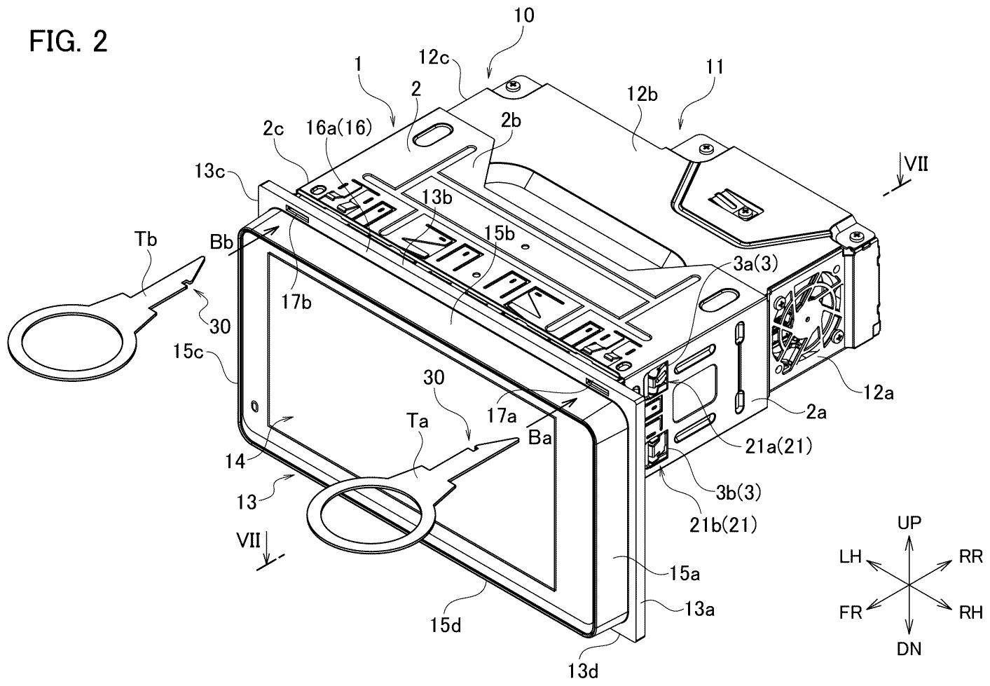

Inside the frame 1 illustrated in FIG. 1, a space S1 defined by the frame wall parts 2a, 2b, 2c, and 2d is formed. The space S1 communicates with the external space in the longitudinal direction of the frame 1. As indicated by the arrow A in FIG. 1, the body part 11 of the device body 10 is inserted into the space S1 from the front of the frame 1 toward the rear, and the device body 10 can be mounted to the frame 1 by engaging a predetermined part of the device body 10 with the frame 1, as illustrated in FIG. 2. Note that a state where the device body 10 is mounted to the frame 1 as exemplified in FIG. 2 is referred to as “mounted state”, and a state where the device body 10 is removed from the frame 1 as exemplified in FIG. 1 is referred to as “removed state”.

The frame 1 exemplified in FIG. 1 includes an inner peripheral edge part 3. The inner peripheral edge part 3 is an edge part to be engaged with an engaging part 21 described below, and the engaging part 21 can be disposed in an opening defined by the inner peripheral edge part 3. That is, the inner peripheral edge part 3 is an edge part defining the opening, where the engaging part 21 is disposed when the device body 10 is mounted to the frame 1. The opening is formed by penetrating a predetermined region of the frame 1 in the thickness direction.

The inner peripheral edge part 3 exemplified in FIG. 1 includes an inner peripheral edge part 3a and an inner peripheral edge part 3b. In the illustrated example, the inner peripheral edge parts 3a and 3b are formed on the frame wall part 2a at a predetermined region on the front side of the frame 1. The inner peripheral edge part 3a is formed in the upper part of the frame wall part 2a, and the inner peripheral edge part 3b is formed in the lower part thereof. Each of the inner peripheral edge part 3a and the inner peripheral edge part 3b has a substantially rectangular shape in an axial view parallel to the width direction of the frame 1. An edge part of the upper side of the frame 1 and an edge part of the lower side of the frame 1 of each of the inner peripheral edge part 3a and the inner peripheral edge part 3b extend in the longitudinal direction of the frame 1. An edge part of the front side of the frame 1 and an edge part of the rear side of the frame 1 of each of the inner peripheral edge part 3a and the inner peripheral edge part 3b extend in the vertical direction of the frame 1. Note that the frame 1 may be a shape substantially symmetric with respect to a plane parallel to the vertical direction passing through the center line in the width direction. Thus, the frame wall part 2c may be formed with inner peripheral edge parts corresponding to the inner peripheral edge parts 3a and 3b.

The device body 10 is disposed on an instrument panel of a vehicle, for example, in the mounted state. That is, the device body 10 is supported by the frame 1 and fixed in the vehicle cabin. The device body 10 includes a first wall part and a second wall part. The first wall part is a wall part configuring one side of the device body 10 in one of the width and the height directions. In the example illustrated in FIG. 1, a side wall part 12a, which will be described below, configuring part of the device body 10 on a device right side in the width direction corresponds to the first wall part. The second wall part is a wall part configuring one side of the device body 10 in the other of the width and height directions. In the illustrated example, an upper wall part 12b, which will be described below, configuring part of the device body 10 on a device upper side in the height direction corresponds to the second wall part.

Note that the first wall part of the device body 10 is not limited to the side wall part 12a, and the second wall part is not limited to the upper wall part 12b. The first wall part and the second wall part may be appropriately set according to the shape of the frame 1 or the device body 10, for example. For example, the upper wall part 12b, which configures the device upper side of the device body 10 in the height direction, may correspond to the first wall part. The side wall part 12a, which configures the device right side of the device body 10 in the width direction may correspond to the second wall part.

The device body 10 exemplified in FIG. 1 includes the body part 11 and a front part 13. The body part 11 configures the body of the device body 10 and may include a controller (not illustrated) or the like for controlling the device body 10 therein. The front part 13 configures a cabin side part of the device body 10. Note that the controller may be a general-purpose microcomputer including a CPU (central processing unit), a memory, an input and output unit, and the like. A computer program including predetermined rules, instructions, and the like for controlling the device body 10 is installed in the memory of the microcomputer. When the computer program is executed, the microcomputer controls the device body 10.

The body part 11 may have a hollow box shape, for example, and may be made from a metal, such as aluminum or stainless steel. The body part 11 extends from part of the front part 13 on a device rear side toward the device rear side. The body part 11 may have a substantially rectangular shape in a cross section perpendicular to the extension direction. When the device body 10 is mounted to the frame 1, the body part 11 is fixed to the frame 1. The body part 11 exemplified in FIG. 1 has a dimension larger in the width direction than that in the height direction but is not limited thereto. The shape and configuration of the body part 11 may be appropriately set according to the shape of the frame 1, for example.

The body part 11 includes the side wall part 12a, the upper wall part 12b, a side wall part 12c, and a lower wall part 12d. The side wall part 12a is a wall part that configures part of the body part 11 on the device right side. The upper wall part 12b is a wall part that configures part of the body part 11 on the device upper side. The side wall part 12c is a wall part that configures part of the body part 11 on the device left side. The lower wall part 12d is a wall part that configures part of the body part 11 on the device lower side. The side wall part 12a, the upper wall part 12b, the side wall part 12c, and the lower wall part 12d configure at least part of a housing forming the exterior surface of the body part 11. A restricting member 20a described below is mounted on the side wall part 12a (see FIG. 3).

In the device body 10, the front part 13 is disposed on the vehicle cabin side relative to the body part 11. The front part 13 exemplified in FIG. 1 has a substantially rectangular shape when viewed in the device longitudinal direction. The front part 13 has a larger dimension than the body part 11 in the width direction. In the illustrated example, a side edge part 13a of the front part 13 on the device right side is positioned outward relative to the side wall part 12a in the device width direction, and a side edge part 13c on the device left side is positioned outward relative to the side wall part 12c in the device width direction. The front part 13 has a larger dimension than the body part 11 in the height direction. An upper edge part 13b of the front part 13 on the device upper side is positioned on the device upper side relative to the upper wall part 12b, and a lower edge part 13d on the device lower side is positioned on the device lower side relative to the lower wall part 12d. That is, the front part 13 and the body part 11 may overlap when viewed in the device longitudinal direction. Note that the shape and configuration of the front part 13 are not limited to the illustrated example.

The front part 13 illustrated in FIG. 1 is provided with a display part 14. The display part 14 has a substantially rectangular shape when viewed in the device longitudinal direction. The display part 14 includes, for example, a capacitive liquid crystal touch panel display and a case for accommodating the liquid crystal touch panel display, and can display various information according to functions of the device body 10. Note that on the display surface of the display part 14, switches operable by an occupant, such as a switch (not illustrated) for operating the device body 10, may be set. The display part 14 incorporates various electrical components, such as a substrate and wiring.

The display part 14 illustrated in FIG. 1 has a smaller dimension than the front part 13 in the width direction. A side edge part 15a of the display part 14 on the device right side is positioned inward relative to the side edge part 13a of the front part 13 in the device width direction, and a side edge part 15c of the display part 14 on the device left side is positioned inward relative to the side edge part 13c of the front part 13 in the device width direction. The display part 14 has a smaller dimension than the front part 13 in the height direction. An upper edge part 15b of the display part 14 on the device upper side is positioned on the device lower side relative to the upper edge part 13b of the front part 13, and a lower edge part 15d on the device lower side is positioned on the device upper side relative to the lower edge part 13d of the front part 13. That is, the display part 14 and the front part 13 may overlap when viewed in the device longitudinal direction.

The display part 14 has a larger dimension than the body part 11 in the width direction. The side edge part 15a is positioned outward relative to the side wall part 12a in the device width direction, and the side edge part 15c is positioned outward relative to the side wall part 12c in the device width direction. The display part 14 has a larger dimension than the body part 11 in the height direction. In the device body 10 exemplified in FIG. 1, the display part 14 is disposed in such a manner that the upper edge part 15b is positioned on the device upper side relative to the upper wall part 12b. The lower edge part 15d is positioned on the device lower side relative to the lower wall part 12d.

In the mounted state, at least part of the frame wall part 2a and the side wall part 12a, and at least part of the frame wall part 2c and the side wall part 12c are shielded by the display part 14 when viewed from the device front (see FIG. 2). Here, as described above, the display part 14 incorporates various electrical components. Thus, the display part 14 does not have an opening for inserting a tool for removing the device body 10 from the frame 1, between the side wall part 12a and the frame wall part 2a. That is, the front part 13 exemplified in FIG. 2 does not have an opening for inserting a tool between the side wall part 12a and the frame wall part 2a. Similarly, the front part 13 does not have an opening for inserting a tool between the side wall part 12c and the frame wall part 2c.

An outer peripheral edge part 16 of the front part 13 is formed on the outer periphery of the display part 14. The outer peripheral edge part 16 is an area of the front part 13 that extends around the display part 14. The outer peripheral edge part 16 may be, for example, a flange formed to extend from the outer periphery part of the display part 14 on the device rear side.

Insertion ports 17a and 17b are formed in the device body 10 exemplified in FIG. 2. The insertion ports 17a and 17b are openings formed in the device body 10 on the vehicle cabin side. Thus, the insertion ports 17a and 17b are formed on the side of a user who uses the device body 10. The insertion ports 17a and 17b are formed by opening the outer peripheral edge part 16 at a predetermined area to penetrate in the device longitudinal direction. In the illustrated example, the insertion ports 17a and 17b are formed in an area of the outer peripheral edge part 16 on the device upper side. That is, the insertion ports 17a and 17b may be formed in an end part 16a of the front part 13 on the device upper side. The insertion port 17a is formed in an area of the end part 16a on the device right side, and the insertion port 17b is formed in an area of the end part 16a on the device left side. Tools Ta and Tb for removing the device body 10 from the frame 1 can be inserted into the insertion ports 17a and 17b. Note that the positions of the insertion ports 17a and 17b are not particularly limited, and for example, the position of the insertion port 17a may be appropriately set according to the position of a space S2 described below.

As exemplified in FIG. 2, in the mounted state, the body part 11 is disposed in the space S1 in such a manner that the outer periphery of the body part 11 is surrounded by the frame 1, and at least part of the side wall part 12a is covered by the frame wall part 2a from the device right side. At least part of the upper wall part 12b is covered by the frame wall part 2b from the device upper side, at least part of the side wall part 12c is covered by the frame wall part 2c from the device left side, and at least part of the lower wall part 12d is covered by the frame wall part 2d from the device lower side.

In the mounted state, the device body 10 is fixed to the frame 1 by engaging the restricting member 20a with the frame wall part 2a. Note that in the example illustrated in FIG. 2, a restricting member (not illustrated) having the same function as the restricting member 20a is disposed in the side wall part 12c and is engaged with the frame wall part 2c. The restricting member is referred to as “second restricting member”. In this case, the restricting member 20a is also referred to as “first restricting member”. By engaging the restricting member 20a and the second restricting member with the frame 1, the device body 10 is fixed to the frame 1 on the device right side and the device left side, and the device body 10 can be more reliably mounted to the frame 1.

In the device body mounting structure exemplified in FIG. 2, the engagement between the restricting member 20a and the frame wall part 2a can be released by inserting the tool Ta into the insertion port 17a. The engagement between the second restricting member and the frame wall part 2c can be released by inserting the tool Tb into the insertion port 17b. Thus, work for removing the device body 10 from the frame 1 can be performed more easily.

Note that the restricting member 20a and the second restricting member have a shape that is substantially symmetric with respect to a plane parallel in the vertical direction, passing through the center line in the width direction of the device body 10. A structure of the side wall part 12a and its vicinity, and a structure of the side wall part 12c and its vicinity, are configured to be substantially symmetric with respect to that plane. That is, part of the body part 11 on the device right side, and part of the body part 11 on the device left side are configured to be substantially symmetric with respect to that plane. However, the configuration of the device body mounting structure is not limited thereto. The part of the body part 11 on the device right side and the part of the body part 11 on the device left side need not be configured to be symmetric with respect to that plane.

Next, referring to FIGS. 3 to 7, the device body mounting structure will be described further. In the following description, the configuration of part of the device body 10 on the device right side will be described as a representative.

As exemplified in FIG. 3, the restricting member 20a is disposed in the device body 10. The restricting member 20a restricts movement of the device body 10 relative to the frame 1 and is disposed on the side wall part 12a. The restricting member 20a, which is exemplified in the figure, is mounted on the side wall part 12a on the inner side of the device body 10. That is, the restricting member 20a is disposed inside the body part 11. The restricting member 20a is arranged at a predetermined position of the side wall part 12a on the device front side. Note that a manner in which the restricting member 20a is mounted on the side wall part 12a is not limited to the illustrated example. For example, the restricting member 20a may be mounted to be along a surface of the side wall part 12a on the outer side in the device width direction. That is, the restricting member 20a may be disposed to be along the exterior surface of the body part 11.

An opening is formed in the side wall part 12a at a predetermined area in each of upper and lower parts, penetrating in the device width direction. An engaging part 21a as a first engaging part described below is disposed inside the opening, which is provided in the upper part of the side wall part 12a, and protrudes outward in the device width direction. An engaging part 21b as a second engaging part described below is disposed inside the opening, which is provided in the lower part of the side wall part 12a, and protrudes outward in the device width direction. In this manner, the engaging parts 21a and 21b may be disposed on the side wall part 12a.

A releasing part 23 of the restricting member 20a, which will be described below, is arranged on the upper wall part 12b at a predetermined position on the inside of the device body 10. The releasing part 23 is disposed in such a manner that at least part of the releasing part 23 and the tool Ta abut against each other when the tool Ta is inserted into the insertion port 17a. In the example illustrated in FIG. 3, an opening surface of the insertion port 17a and at least part of the releasing part 23 face each other in the device longitudinal direction.

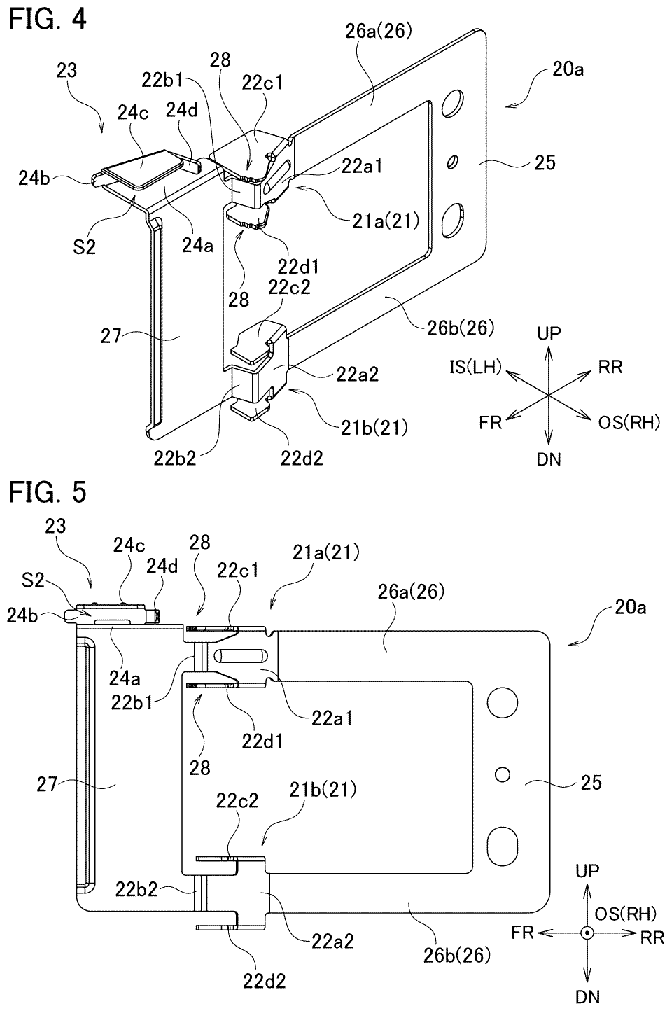

The restricting member 20a exemplified in FIGS. 4, 5 and 6 is a plate-like member having a substantially rectangular shape when viewed in an axial direction parallel to the device width direction. The restricting member 20a, when mounted on the side wall part 12a, extends as a whole in the device longitudinal direction (see FIG. 3). The restricting member 20a may be formed, for example, by performing bending processing on a metal plate having a predetermined spring property. The restricting member 20a includes the engaging part 21 and the releasing part 23. In the illustrated example, the restricting member 20a includes a fixing part 25, an arm part 26, and a connecting part 27.

The fixing part 25 is part of the restricting member 20a, which is fixed to the side wall part 12a. The fixing part 25 is formed to extend in the device vertical direction on the device rear side of the restricting member 20a. A means for fixing the fixing part 25 to the side wall part 12a is not particularly limited. For example, a protruding part formed on a surface of the side wall part 12a on the inner side in the device width direction may be inserted into an opening formed in the fixing part 25, and fixation may be achieved by crimping. Alternatively, the fixing part 25 may be fastened to the side wall part 12a using a fastener, such as a bolt.

The arm part 26 is formed to extend from the fixing part 25 toward the device front. The engaging part 21 is formed at an end part of the arm part 26, opposite to the fixing part 25 in the extending direction. The arm part 26 exemplified in FIG. 4 includes an arm part 26a as a first arm part, and an arm part 26b as a second arm part. The arm parts 26a and 26b have a substantially rectangular shape in a cross section perpendicular to the extending direction, and function as a plate spring.

The arm part 26a extends from part of the fixing part 25 on the device upper side, and forms at least part of the restricting member 20a on the device upper side. The engaging part 21a is formed at an end part of the arm part 26a at the device front side. Thus, the arm part 26a connects the fixing part 25 and the engaging part 21a. The arm part 26b extends from part of the fixing part 25 on the device lower side, and forms at least part of the restricting member 20a on the device lower side. The engaging part 21b is formed at an end part of the arm part 26b at the device front side. Thus, the arm part 26b connects the fixing part 25 and the engaging part 21b. That is, the arm part 26 connects each of the engaging parts 21a and 21b with the fixing part 25.

When the restricting member 20a is disposed on the side wall part 12a, the engaging part 21 protrudes outward in the device width direction (see FIG. 3). In the mounted state, the part of the side wall part 12a, where the restricting member 20a is disposed, is covered by the frame wall part 2a from the device right (see FIGS. 2 and 3). That is, in the mounted state, the engaging part 21 protrudes toward the frame wall part 2a. Then, part of the engaging part 21 engages with the inner peripheral edge part 3 of the frame wall part 2a. That is, the engaging part 21 is part of the restricting member 20a, which engages with the frame wall part 2a.

The engaging part 21 exemplified in FIG. 4 includes the engaging part 21a and the engaging part 21b. The engaging part 21a is included in the engaging part 21, which is formed on part of the restricting member 20a on the device upper side. The engaging part 21b is included in the engaging part 21, which is formed on part of the restricting member 20a on the device lower side. In the mounted state, the engaging part 21a engages with the inner peripheral edge part 3a, and the engaging part 21b engages with the inner peripheral edge part 3b (see FIG. 2). In this manner, the engaging part 21 may include the multiple engaging parts 21a and 21b, which are engaged with the frame wall part 2a.

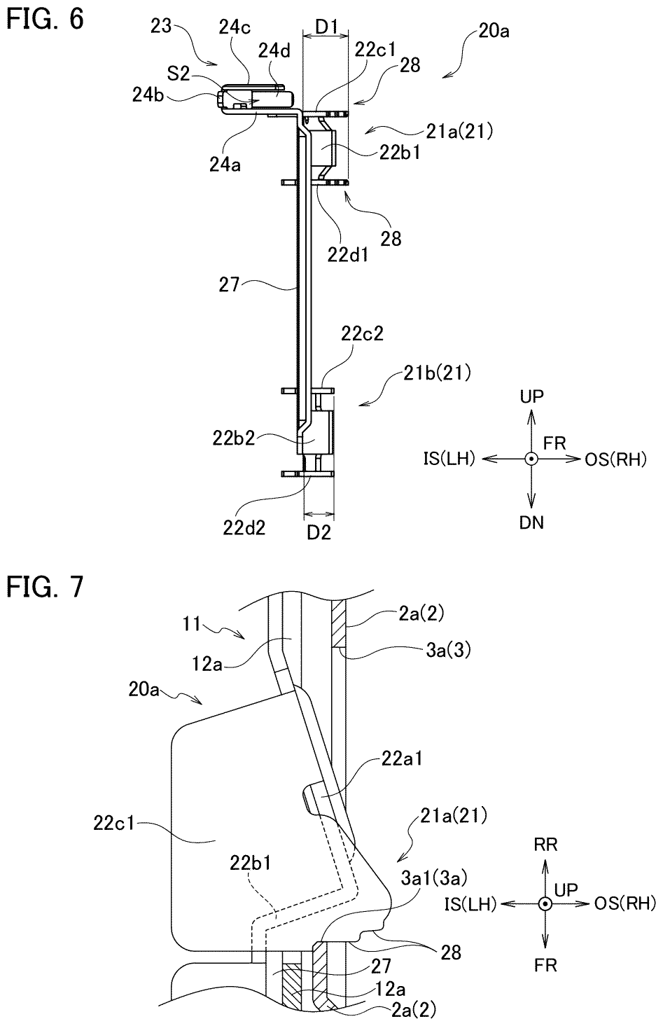

As exemplified in FIG. 6, the engaging part 21a and the engaging part 21b have substantially the same positions in the device width direction. In other words, each of the engaging parts 21a and 21b is arranged in parallel along the side wall part 12a in a first direction perpendicular to the depth direction of the device body 10. In the illustrated example, the device vertical direction corresponds to the first direction. The engaging part 21a is positioned above the engaging part 21b in the device vertical direction. Thus, among the multiple engaging parts 21a and 21b, the engaging part 21a is arranged more toward the releasing part 23 in the device vertical direction. The engaging part 21b, from among the multiple engaging parts 21a and 21b, is arranged at a position farther from the releasing part 23 relative to the engaging part 21a in the device vertical direction.

In the example illustrated in FIG. 6, a first protrusion amount D1 of the engaging part 21a is larger than a second protrusion amount D2 of the engaging part 21b. The first protrusion amount D1 is a protrusion amount of the engaging part 21a toward the frame wall part 2a from the connecting part 27. In the illustrated example, end parts of wall parts 22c1 and 22d1, which will be described below, of the engaging part 21a on the outer side in the device width direction form a part farthest from the connecting part 27 in the device width direction. Thus, the dimension in the device width direction between the connecting part 27 and the part of the wall parts 22c1 and 22d1 farthest from the connecting part 27 in the device width direction corresponds to the first protrusion amount D1. The second protrusion amount D2 is a protrusion amount of the engaging part 21b toward the frame wall part 2a from the connecting part 27. End parts of wall parts 22c2 and 22d2, which will be described below, of the engaging part 21b on the outer side in the device width direction form a part farthest from the connecting part 27 in the device width direction. Thus, the dimension in the device width direction between the connecting part 27 and the part of the wall parts 22c2, 22d2 farthest from the connecting part 27 in the device width direction corresponds to the second protrusion amount D2.

A bending rigidity of the arm part 26b in a second direction perpendicular to the depth direction and the first direction may be lower than that of the arm part 26a in the second direction. In the examples illustrated in FIGS. 4 and 5, the device width direction perpendicular to the depth direction and the device vertical direction of the device body 10 correspond to the second direction. Note that the method of adjusting the bending rigidity of the arm part 26a and the arm part 26b in the device width direction is not particularly limited, and a known method may be used appropriately. For example, the dimension of the arm part 26b in the device vertical direction may be made smaller than that of the arm part 26a in the device vertical direction. The thickness of the arm part 26b may be made smaller than that of the arm part 26a in the device width direction. In addition, for example, a rib may be formed on the arm part 26a, extending along the extension direction in such a manner that a cross-sectional secondary moment of the arm part 26a becomes larger than that of the arm part 26b.

The engaging part 21a exemplified in FIG. 4 includes a wall part 22a1 and a wall part 22b1. The wall part 22a1 is a wall part to which the arm part 26a is directly connected, and extends inclined relative to the device longitudinal direction in plan view. The wall part 22a1 is formed to be positioned outward in the device width direction as it extends from a device rear side end part toward the device front. The wall part 22b1 is a wall part extending from a device front side end part of the wall part 22a1 toward the connecting part 27, and extends inclined relative to the device longitudinal direction in plan view. The wall part 22b1 is formed positioned inward in the device width direction as it extends from the device rear side end part toward the device front. Note that the wall parts 22a1 and 22b1 are also referred to as first rear inclined part and first front inclined part, respectively.

In the example illustrated in FIG. 4, the engaging part 21a includes a wall part 22c1 and a wall part 22d1. The wall part 22c1 is formed to extend from an edge part of the wall part 22a1 on the device upper side inward in the device width direction, and forms the device upper side of the engaging part 21a. The wall part 22d1 is formed to extend from an edge part of the wall part 22a1 on the device lower side inward in the device width direction, and forms the device lower side of the engaging part 21a. Each of the wall part 22c1 and the wall part 22d1 may extend substantially in the device longitudinal direction. Note that the wall parts 22c1 and 22d1 may be referred to as first upper extended part and first lower extended part, respectively.

Note that the engaging part 21a and the engaging part 21b may have substantially the same shape. Thus, the engaging part 21b may have a wall part 22a2 corresponding to the wall part 22a1, a wall part 22b2 corresponding to the wall part 22b1, a wall part 22c2 corresponding to the wall part 22c1, and a wall part 22d2 corresponding to the wall part 22d1. Note that the wall parts 22a2 and 22b2 may be referred to as second rear inclined part and second front inclined part, respectively. The wall parts 22c2 and 22d2 may be referred to as second upper extended part and second lower extended part, respectively.

As exemplified in FIG. 7, multiple abutting parts 28 are formed on an edge part of the wall part 22c1 on the device front side. The edge part is part of the engaging part 21a, which abuts against the inner peripheral edge part 3a when the frame wall part 2a is engaged with the engaging part 21a. That is, the engaging part 21a may have the multiple abutting parts 28, which are capable of abutting against the inner peripheral edge part 3a when the frame wall part 2a is engaged with the engaging part 21a. When the engaging part 21a is engaged with the inner peripheral edge part 3a, any of the multiple abutting parts 28 abuts against the inner peripheral edge part 3a. In the illustrated example, among the multiple abutting parts 28, the abutting part 28 positioned inward in the device width direction abuts against the edge part 3a1 of the inner peripheral edge part 3a. The edge part 3a1 configures the device front side of the inner peripheral edge part 3a, and extends in the device vertical direction.

In the example illustrated in FIG. 7, each of the multiple abutting parts 28 extends in the device width direction to intersect with the edge part 3a1. That is, each of the multiple abutting parts 28 may extend in a direction intersecting with an opening surface defined by the inner peripheral edge part 3a. Further, each of the multiple abutting parts 28 has a different position in the device longitudinal direction, and in the illustrated example, each of the multiple abutting parts 28 is arranged more toward the device front side as the location becomes more inward in the device width direction. Thus, a stepped part having a stepped shape in plan view is formed on the edge part of the wall part 22c1 on the device front side. The stepped part is formed on the edge part of the wall part 22c1 on the device front side, at the outer part in the device width direction. A stepped part corresponding to the stepped part may also be formed on the wall part 22d1. Note that the multiple abutting parts 28 are not formed on the wall part 22c2 and the wall part 22d2 of the engaging part 21b exemplified in FIG. 4, but this is not limiting. For example, a stepped part corresponding to the multiple abutting parts 28 may be formed on each of the wall part 22c2 and the wall part 22d2 of the engaging part 21b.

The connecting part 27 is a part connecting the engaging parts 21a and 21b to each other. The connecting part 27 exemplified in FIG. 4 has a plate-like shape extending in the device vertical direction, and forms at least part of the restricting member 20a on the device front side. The upper part of the end part of the connecting part 27 on the device rear side may be connected to the end part of the wall part 22b1 on the device front side, and the lower part thereof may be connected to the end part of the wall part 22b2 on the device front side.

The releasing part 23 extends from an end part of the connecting part 27 on the device upper side inward in the device width direction. As exemplified in FIG. 4, the releasing part 23 is connected to the engaging parts 21a and 21b via the connecting part 27. That is, the releasing part 23 is a part connected to the engaging part 21. As exemplified in FIG. 3, when the restricting member 20a is mounted on the side wall part 12a, the releasing part 23 is arranged inside the body part 11 in the vicinity of a surface of the upper wall part 12b on the device lower side. However, the position of the releasing part 23 is not limited to the illustrated example. For example, when the restricting member 20a is mounted on a surface of the side wall part 12a on the outer side in the device width direction, the releasing part 23 may be arranged outside the body part 11 in the vicinity of a surface of the upper wall part 12b on the device upper side. In other words, the releasing part 23 may be disposed along the upper wall part 12b.

The releasing part 23 exemplified in FIG. 4 includes a wall part 24a, a wall part 24b, a wall part 24c, and a wall part 24d. The wall part 24a extends from the end part of the connecting part 27 on the device upper side inward in the device width direction. The wall part 24a may be formed by bending the end part of the connecting part 27 on the device upper side inward in the device width direction. The wall part 24b is erected at an end part of the wall part 24a on the inner side in the device width direction. The wall part 24b may be formed by bending the inner side of the wall part 24a in the device width direction toward the device upper side. The wall part 24c extends from an end part of the wall part 24b on the device upper side outward in the device width direction. The wall part 24c may be formed by bending the end part of the wall part 24b on the device upper side outward in the device width direction. The wall part 24d extends from an end part of the wall part 24b on the device rear side outward in the device width direction. The wall part 24d may be formed by bending the end part of the wall part 24b on the device rear side outward in the device width direction. In the illustrated example, the space S2 is defined by the wall part 24a, the wall part 24b, the wall part 24c, and the wall part 24d. The space S2 communicates with the outside of the device body 10 through the insertion port 17a (see FIG. 3). Note that the wall part 24a is also called a base part. The wall part 24b is also called a erecting part. The wall part 24c is also called an eaves part. The wall part 24d is also called a pressed part.

The releasing part 23 has a part that is pressed in a direction away from the frame wall part 2a by the tool Ta when the tool Ta is inserted through the insertion port 17a. In the releasing part 23 exemplified in FIG. 4, the wall part 24d corresponds to that part.

Note that the shape of the restricting member 20a is not limited to the examples illustrated in FIGS. 3 to 7. For example, the arm part 26 and the engaging part 21 may each be formed one by one on the restricting member 20a. It is sufficient that the releasing part 23 may be connected to only one engaging part 21. In this case, it is sufficient that one inner peripheral edge part 3, which can be engaged with the engaging part 21, may be formed on the frame wall part 2a.

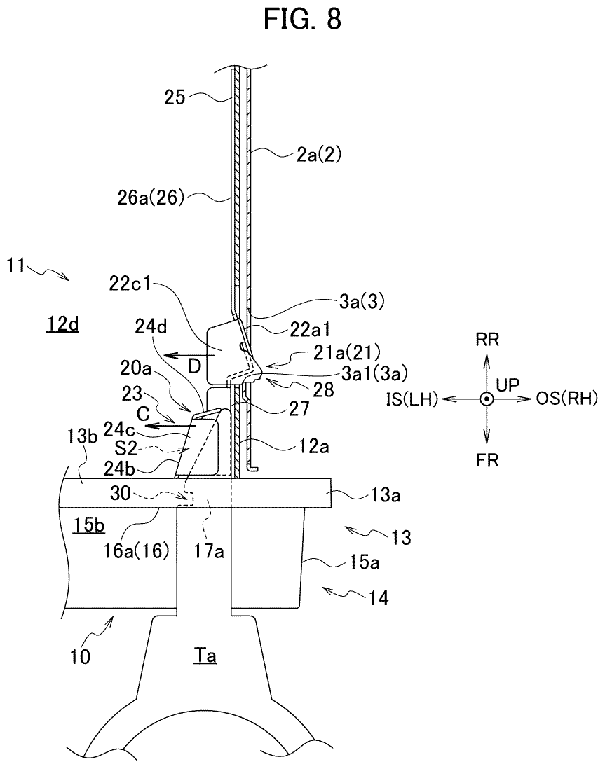

Next, the behavior of the restricting member 20a when the tool Ta is inserted through the insertion port 17a will be described with reference to FIG. 2, and FIGS. 8 to 10. Note that in FIGS. 8 to 10, the display of the engaging part 21b is omitted. As described above, the part of the body part 11 on the device right side, and the part of the body part 11 on the device left side exemplified in FIG. 1 are substantially symmetrical relative to a plane parallel in the vertical direction passing through the center line in the width direction of the device body 10. Thus, the behavior of the second restricting member when the tool Tb is inserted through the insertion port 17b becomes substantially symmetrical with respect to the behavior of the restricting member 20a relative to the corresponding surface. Thus, description of the behavior of the second restricting member will be omitted.

In the state illustrated in FIG. 8, the device body 10 is mounted to the frame 1. Thus, the engaging part 21a is engaged with the inner peripheral edge part 3a of the frame wall part 2a. More specifically, one of the multiple abutting parts 28 of the engaging part 21a abuts against the edge part 3a1 of the inner peripheral edge part 3a, and thus the engaging part 21a is engaged with the inner peripheral edge part 3a. In this state, the engaging part 21a is disposed in the opening defined by the inner peripheral edge part 3a. When the device body 10 is moved toward the device front in order to remove the device body 10 from the frame 1, one of the multiple abutting parts 28 formed in the engaging part 21a abuts against the edge part 3a1. Thus, the movement of the device body 10 to the device front is restricted.

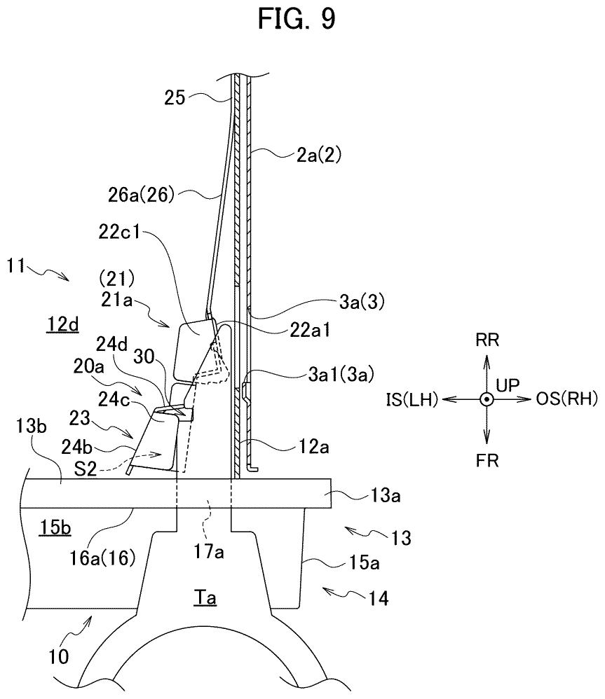

When the device body 10 is removed from the frame 1, the tool Ta is inserted into the insertion port 17a, as indicated by the arrow Ba in FIG. 2. Thus, as exemplified in FIG. 8, a tip part of the tool Ta is inserted into the space S2 via the insertion port 17a. The tip part of the tool Ta abuts against the wall part 24d of the releasing part 23. Then, by pushing the tool Ta toward the device rear, the wall part 24d is pressed by the tip part of the tool Ta inward in the device width direction. That is, when the tool Ta is inserted through the insertion port 17a, the wall part 24d is pressed by the tool Ta in a direction away from the frame wall part 2a. Thus, the releasing part 23 moves in the direction away from the frame wall part 2a, as indicated by the arrow C in the figure. Here, the restricting member 20a is fixed to the side wall part 12a in the fixing part 25. Thus, as exemplified in FIG. 9, part of the restricting member 20a on the device front side relative to the fixing part 25 is displaced inward in the device width direction to rotate in a predetermined angle range with the fixing part 25 as a fulcrum. That is, the restricting member 20a is bent inward in the device width direction with the fixing part 25 as a fulcrum. Accordingly, the engaging part 21a is also displaced inward in the device width direction as illustrated by the arrow D in FIG. 8, and the engagement between the engaging part 21a and the inner peripheral edge part 3a is released as exemplified in FIG. 9. Note that although not illustrated, the engagement between the engaging part 21b and the inner peripheral edge part 3b is also released by the bending of the restricting member 20a.

Note that in the example illustrated in FIG. 2, the second restricting member is disposed on the side wall part 12c of the body part 11. Thus, by inserting the tool Tb into the insertion port 17b, the second restricting member is bent inward in the device width direction as well as the restricting member 20a, and the engagement between the second restricting member and the frame wall part 2c can be released. Thus, the fixing of the device body 10 to the frame 1 is released. Therefore, the device body 10 can be removed from the frame 1 by moving the device body 10 toward the device front.

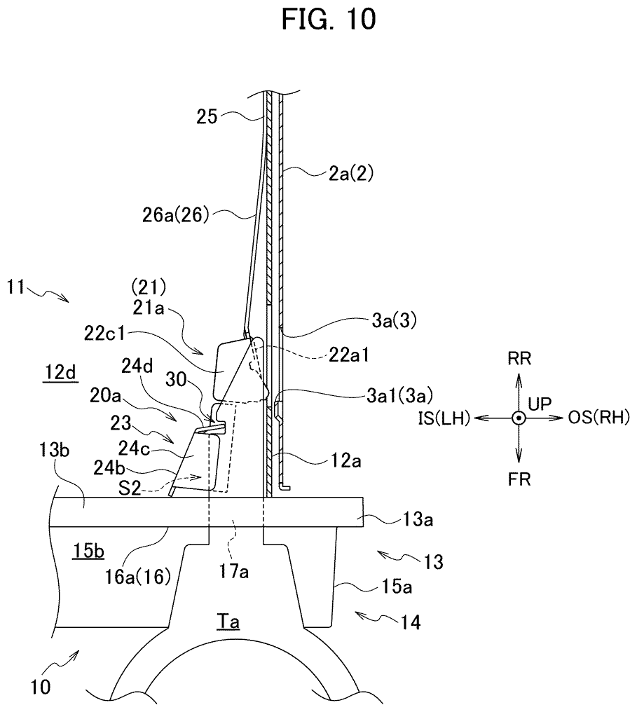

FIG. 10 illustrates a state where the tool Ta is pushed farther into the insertion port 17a from the state exemplified in FIG. 9. In the illustrated state, an end part of the wall part 24d on a frame wall part 2a side is engaged with a recessed part 30 of the tool Ta. The recessed part 30 is a part formed in the tool Ta, which can be engaged with the end part. That is, the releasing part 23 has a part that abuts against the recessed part 30 of the tool Ta when the tool Ta is inserted through the insertion port 17a. The recessed part 30 may be formed at a predetermined position of the tool Ta inside the device width direction in a state where the tool Ta is inserted into the insertion port 17a. For example, the recessed part 30 may be formed by cutting a predetermined position of the tool Ta. Note that the end part of the wall part 24d on the frame wall part 2a side may abut against the recessed part 30 to press the tool Ta toward the frame wall part 2a side.

In the example illustrated in FIG. 2, in a state where the tool Ta is inserted into the insertion port 17a, and the tool Tb is inserted into the insertion port 17b, the tool Ta and the tool Tb have a shape that is substantially symmetrical to a parallel plane in the vertical direction, passing through the center line of the device body 10 in the device width direction. Thus, a recessed part corresponding to the recessed part 30 is formed on a side of the tool Tb inward in the device width direction in a state where the tool Tb is inserted into the insertion port 17b. Thus, the part corresponding to the wall part 24d of the second restricting member can be engaged with the recessed part of the tool Ta.

When the device body 10 is taken out of the frame 1, the tool Ta is pulled toward the device front from the state illustrated in FIG. 10. Similarly, the tool Tb inserted into the insertion port 17b is pulled toward the device front. Thus, the tool Ta, the tool Tb, and the device body 10 can be moved integrally. At this time, on the device right side of the device body 10, a state is maintained where the engagement between the restricting member 20a and the frame wall part 2a is released. Similarly, on the device left side of the device body 10, a state is maintained where the engagement between the second restricting member and the frame wall part 2c is released.

Note that in the example illustrated in FIG. 10, a gap is formed between part of the tool Ta on the frame wall part 2a side, and the side wall part 12a, but this is not limiting. When the tool Ta is inserted into the insertion port 17a, the part of the tool Ta on the frame wall part 2a side may contact with the side wall part 12a. Thus, a state where the engagement between the engaging parts 21a, 21b and the frame wall part 2a is released can be more reliably maintained.

In the above description, the device body mounting structure has been described by taking the case where the second restricting member is disposed on the side wall part 12c of the body part 11 as an example, but this is not limiting. For example, only the restricting member 20a may be disposed on the body part 11. In this case, only the insertion port 17a may be formed in the device body 10 without forming the insertion port 17b. In addition, the device body 10 may be removed from the frame 1 by inserting the tool Ta into the insertion port 17a.

### (Modification)

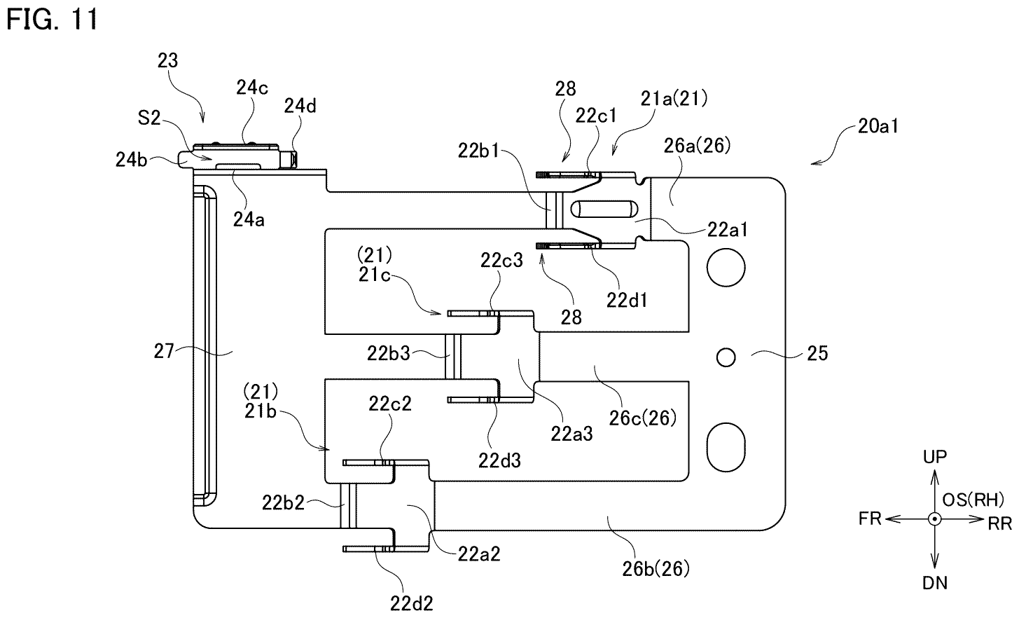

Next, a restricting member 20a1 of the device body mounting structure according to a modification of the embodiment will be described with reference to FIG. 11. In the device body mounting structure, the restricting member 20a1 may be used instead of the restricting member 20a. That is, the restricting member 20a1 corresponds to the restricting member 20a.

In addition to the engaging parts 21a and 21b, the restricting member 20a1 is formed with an engaging part 21c as a third engaging part described below. Thus, the frame wall part 2a is formed with an inner peripheral edge part positioned between the inner peripheral edge part 3a and the inner peripheral edge part 3b in the height direction of the frame 1. The inner peripheral edge part may be formed by opening the frame wall part 2a at a predetermined position to penetrate the frame 1 in the width direction. By engaging the engaging part 21c with the inner peripheral edge part, the device body 10 can be more reliably mounted to the frame 1.

The restricting member 20a1 may be a plate-like member having a substantially rectangular shape when viewed in the axial direction parallel to the device width direction, in the same manner as the restricting member 20a, and may be formed, for example, by performing bending processing on a metal plate having a predetermined spring property. The restricting member 20a1 differs from the restricting member 20a in that it includes the engaging part 21c, and an arm part 26c as a third arm part. That is, in the restricting member 20a1 of the device body mounting structure, the engaging part 21 includes the engaging part 21a, the engaging part 21b, and the engaging part 21c, and the arm part 26 includes the arm part 26a, the arm part 26b, and the arm part 26c.

The arm part 26c exemplified in FIG. 11 is formed to extend from the fixing part 25 toward the device front. The arm part 26c extends from the fixing part 25 to be positioned between the arm part 26a and the arm part 26b in the device vertical direction. The arm part 26c has a substantially rectangular shape in a cross section perpendicular to its extending direction, and may function as a plate spring. An engaging part 21c is formed at an end part of the arm part 26c on the device front side. That is, the arm part 26c connects the fixing part 25 and the engaging part 21c.

The engaging part 21c is formed to be positioned between the engaging part 21a and the engaging part 21b in the device vertical direction. The engaging part 21c protrudes outward in the device width direction in a state where the restricting member 20a1 is disposed on the side wall part 12a. The engaging part 21c protrudes toward the frame wall part 2a in the mounted state.

In the restricting member 20a1 exemplified in FIG. 11, the engaging part 21a is disposed on the device rear side relative to the engaging part 21b. Thus, the length of the arm part 26a may be shorter than that of the arm part 26b. The position of the engaging part 21c may be set to be positioned between the engaging part 21a and the engaging part 21b in the device longitudinal direction. Here, the length of the arm part 26c may be longer than that of the arm part 26a, and shorter than that of the arm part 26b. The bending rigidity of the arm part 26c may be lower than that of the arm part 26a, and higher than that of the arm part 26b in the device width direction. The method of adjusting the bending rigidity of the arm part 26a, the arm part 26b, and the arm part 26c is not particularly limited, and a known method may be used appropriately.

The positions of the engaging parts 21a, 21b, and 21c exemplified in FIG. 11 in the device width direction are substantially equal. In other words, the engaging parts 21a, 21b, and 21c are arranged in parallel in the device vertical direction, which is the first direction perpendicular to the depth direction of the device body, to be along the side wall part 12a.

The engaging part 21c exemplified in FIG. 11 has substantially the same shape as the engaging part 21a or 21b. Thus, the engaging part 21c has a wall part 22a3 corresponding to the wall part 22a1, a wall part 22b3 corresponding to the wall part 22b1, a wall part 22c3 corresponding to the wall part 22c1, and a wall part 22d3 corresponding to the wall part 22d1. At least one of the wall part 22c3 or the wall part 22d3 may have a stepped part corresponding to the multiple abutting parts 28. Note that the wall parts 22a3 and 22b3 are also referred to as third rear side inclined part and third front side inclined part, respectively. The wall parts 22c3 and 22d3 are also referred to as third upper side extended part and third lower side extended part, respectively.

The connecting part 27 exemplified in FIG. 11 connects each of the engaging part 21a, the engaging part 21b, and the engaging part 21c to each other. The upper part of the connecting part 27 extends toward the engaging part 21a and is connected to the wall part 22b1, and the lower part thereof extends toward the engaging part 21b and is connected to the wall part 22b2. The substantially central part of the connecting part 27 in the device vertical direction extends toward the engaging part 21c and is connected to the wall part 22b3.

Note that the shape of the restricting member 20a1 is not limited to the illustrated example. For example, positions, shapes, and the like of the engaging parts 21a, 21b, and 21c may be appropriately changed according to shapes, configurations, and the like of the frame 1 and the device body 10.

Operations and effects of the device body mounting structure according to the embodiment will be described below.

(1) A device body mounting structure includes the frame 1 disposed in a recessed space opened to a user side, and the device body 10 configured to be mounted to the frame 1. The frame 1 includes the frame wall part 2 configured to cover at least part of the device body 10. The device body 10 includes a first wall part configuring one side of the device body 10 in one of a width direction and a height direction, and a second wall part configuring one side of the device body 10 in the other of the width direction and the height direction. The device body 10 includes the restricting member 20a disposed on the first wall part and configured to restrict movement of the device body 10 with respect to the frame 1, and the insertion port 17a formed on the device body 10 on the user side and configured such that a tool Ta for removing the device body 10 from the frame 1 can be inserted therein. The restricting member 20a is formed with the engaging part 21 disposed on the first wall part, and protruding toward the frame wall part 2 and configured to be engaged with the frame wall part 2, and the releasing part 23 disposed along the second wall part and connected to the engaging part 21. The releasing part 23 includes the part 24d configured to be pressed by the tool Ta in a direction away from the frame wall part 2 when the tool Ta is inserted through the insertion port 17a.

In the above-described structure, the releasing part 23 can be moved in a direction away from the frame wall part 2 by inserting the tool Ta into the insertion port 17a of the device body 10. Here, the engaging part 21 connected to the releasing part 23 moves in a direction away from the frame wall part 2 as the releasing part 23 moves. Thus, for example, even when a removing tool for releasing the engagement between the frame wall part 2 and the engaging part 21 cannot be inserted between the frame wall part 2 and the first wall part due to the structure of the front part 13 of the device body 10, the releasing part 23 can be moved using the tool Ta. Then, the engagement between the frame wall part 2 and the engaging part 21 can be released. Thus, the work of removing the device body 10 from the frame 1 can be more easily performed.

(2) The device body 10 may include the body part 11 configured to be mounted to the frame 1, and the front part 13 having a dimension larger than the body part 11 in the width direction, and disposed on the user side relative to the body part 11. The first wall part configures the side wall part 12a of the body part 11 on one side in the width direction, the second wall part configures the upper wall part 12b of the body part 11 on the upper side, and the insertion port 17a may be formed at the end part 16a of the front part 13 on the upper side.

In the above configuration, the first wall part of the body part 11 configures the side wall part 12a. The restricting member 20a is disposed on the side wall part 12a. Since the insertion port 17a is formed at the end part 16a of the front part 13 on the upper side, the releasing part 23 disposed at the upper wall part 12b of the body part 11 can be pressed in a direction away from the frame wall part 2a by inserting the tool Ta into the insertion port 17a. Thus, for example, even when a wide liquid crystal panel is disposed at the front part 13 of the device body 10 and a removing tool cannot be inserted between the side wall part 12a and the frame wall part 2a, the engagement between the engaging part 21 and the frame wall part 2a can be released using the tool Ta. That is, the device body 10 can be more easily removed from the frame 1.

(3) The engaging part 21 may include the plurality of engaging parts 21a, 21b configured to be engaged with the frame wall part 2. The restricting member 20a may include the fixing part 25 configured to be fixed to the first wall part, an arm part 26 connecting each of the engaging parts 21a, 21b and the fixing part 25, and a connecting part 27 connecting the engaging parts 21a, 21b to each other.

In the above structure, the device body 10 can be more reliably fixed to the frame 1 due to the engaging parts 21a and 21b. Furthermore, when the releasing part 23 moves in a direction away from the frame wall part 2, each of the engaging parts 21a and 21b moves in a direction away from the frame wall part 2 to operate in conjunction with each other, with the fixing part 25 serving as a fulcrum. That is, by inserting the tool Ta into the insertion port 17a, the engagement of each of the engaging parts 21a and 21b with the frame wall part 2 can be released. Thus, the work of removing the device body 10 from the frame 1 can be more easily performed.

(4) Each of the plurality of engaging parts 21a and 21b may be arranged in parallel in the first direction perpendicular to the depth direction of the device body 10 to be along the first wall part. The plurality of engaging parts 21a and 21b may include the first engaging part 21a arranged more toward the releasing part 23 in the first direction, and the second engaging part 21b arranged farther from the releasing part 23 than the first engaging part 21a in the first direction. The first protrusion amount D1 of the first engaging part 21a from the connecting part 27 toward the frame wall part 2 may be larger than the second protrusion amount D2 of the second engaging part 21b from the connecting part 27 toward the frame wall part 2a.

In the above configuration, by setting the second protrusion amount D2 smaller than the first protrusion amount D1, the protrusion amount of the engaging part 21b from the inner peripheral edge part 3b becomes smaller than that of the engaging part 21a from the inner peripheral edge part 3a. Thus, when the tool Ta is inserted into the insertion port 17a, the engagement between the engaging part 21b and the inner peripheral edge part 3b can be released more easily. That is, even when the distance between the engaging part 21b and the releasing part 23 in the first direction is longer than that between the engaging part 21a and the releasing part 23, the engagement between the engaging part 21b and the frame wall part 2 can be released more easily. For example, as illustrated in FIG. 6, the engaging part 21b is disposed farther from the releasing part 23 than the engaging part 21a in the device vertical direction. Thus, when the tool Ta is inserted into the insertion port 17a, and the releasing part 23 moves inward in the device width direction, the moving distance of the engaging part 21b inward in the device width direction may be shorter than that of the engaging part 21a inward in the device width direction. Even in such a case, the engagement between the engaging part 21b and the frame wall part 2 can be released more easily, and the work of removing the device body 10 from the frame 1 can be performed more easily.

Note that when the tool Ta is inserted into the insertion port 17a, and the releasing part 23 is pressed by the tool Ta in a direction away from the frame wall part 2, the engagement between the engaging part 21a and the frame wall part 2, and the engagement between the engaging part 21b and the frame wall part 2 may be released almost simultaneously. Thus, the work of removing the device body 10 from the frame 1 can be performed more reliably.

(5) Each of the plurality of engaging parts 21a and 21b may be arranged in parallel along the first wall part in a first direction perpendicular to the depth direction of the device body 10. The plurality of engaging parts 21a and 21b may include the first engaging part 21a arranged more toward the releasing part 23 in the first direction, and the second engaging part 21b arranged farther from the releasing part 23 than the first engaging part 21a in the first direction. The arm part 26 may include the arm part 26a connecting the fixing part 25 and the first engaging part 21a, and the arm part 26b connecting the fixing part 25 and the second engaging part 21b. Here, the length of the arm part 26a may be shorter than that of the arm part 26b, or the bending rigidity of the arm part 26b in the second direction perpendicular to the depth direction and the first direction may be lower than that of the arm part 26a in the second direction.

In the above-described configuration, the device body mounting structure can be configured such that the moving distance of the engaging part 21b in the second direction is greater than or equal to the moving distance of the engaging part 21a in the second direction when the tool Ta is inserted into the insertion port 17a. For example, in the example illustrated in FIG. 11, the length of the arm part 26a is shorter than that of the arm part 26b. Thus, the engaging part 21b is positioned farther from the fixing part 25 than the engaging part 21a in the device longitudinal direction. Accordingly, the moving distance of the engaging part 21b in the device width direction can be made longer in a case where the tool Ta is inserted into the insertion port 17a, and the releasing part 23 is moved inward in the device width direction. For example, by setting the bending rigidity of the arm part 26b in the device width direction lower than that of the arm part 26a in the device width direction, the arm part 26b can be bent more inward in the device width direction according to the movement of the releasing part 23. Thus, the moving distance of the engaging part 21b in the device width direction can be made longer in a case where the tool Ta is inserted into the insertion port 17a, and the releasing part 23 is moved inward in the device width direction. Thus, the engagement between the engaging part 21b and the frame wall part 2 can be more easily released.

Note that the frame wall part 2 may be formed with the inner peripheral edge part 3 with which the engaging part 21 engages. The engaging part 21 may include the multiple abutting parts 28, which can abut against the inner peripheral edge part 3 when the engaging part 21 and the frame wall part 2a engage. Each of the multiple abutting parts 28 may extend in a direction intersecting the opening surface defined by the inner peripheral edge part 3.

Thus, for example, a stepped part having a stepped shape in plan view is formed at the edge part of the wall part 22c1 of the engaging part 21a on the device front side. Thus, even if, for example, there is a tolerance in the dimension, shape, or the like during the manufacturing process of the restricting member 20a, any of the multiple abutting parts 28 can abut against the inner peripheral edge part 3a when the engaging part 21a is engaged with the inner peripheral edge part 3a. Thus, the device body 10 can be more reliably fixed to the frame 1.

Note that the releasing part 23 may include the part 24d to be engaged with the recessed part 30, which is formed in the tool Ta, when the tool Ta is inserted through the insertion port 17a.

Thus, when the tool Ta is inserted into the insertion port 17a, for example, the end part of the wall part 24d on the side of the frame wall part 2a engages with the recessed part 30. Thus, when the tool Ta is pulled, the end part is hung on the recessed part 30, and the tool Ta and the device body 10 can be moved integrally. Thus, the device body 10 can be more easily removed from the frame 1.

According to the present embodiment, it is possible to provide a device body mounting structure where the device body can be more easily removed from the frame.

1. A device body mounting structure comprising:
a frame disposed in a recessed space opened to a user side; and
a device body configured to be mounted to the frame, wherein
the frame includes a frame wall part configured to cover at least part of the device body,
the device body includes:
a first wall part configuring one side of the device body in one of a width direction and a height direction;
a second wall part configuring one side of the device body in the other of the width direction and the height direction;
a restricting member disposed on the first wall part and configured to restrict movement of the device body with respect to the frame; and
an insertion port formed on the device body on the user side and configured such that a tool for removing the device body from the frame can be inserted therein,
the restricting member is formed with:
a plurality of engaging parts disposed on the first wall part, and protruding toward the frame wall part and configured to be engaged with the frame wall part; and
a releasing part disposed along the second wall part and connected to the plurality of engaging parts,
the releasing part includes a part configured to be pressed by the tool in a direction away from the frame wall part when the tool is inserted through the insertion port, and
the restricting member is provided with:
a fixing part configured to be fixed to the first wall part;
an arm part connecting each of the plurality of engaging parts to the fixing part; and
a connecting part connecting the plurality of engaging parts to each other.

2. The device body mounting structure according to claim 1, wherein
the device body includes:
a body part configured to be mounted to the frame; and
a front part having a dimension larger than the body part in the width direction, and disposed on the user side relative to the body part,
the first wall part configures a part of the body part on one side in the width direction,
the second wall part configures a part of the body part on an upper side, and
the insertion port is formed at an end part of the front part on the upper side.

3. The device body mounting structure according to claim 1, wherein
each of the plurality of engaging parts is arranged in parallel in a first direction perpendicular to a depth direction of the device body to be along the first wall part,
the plurality of engaging parts includes:
a first engaging part arranged more toward the releasing part in the first direction; and
a second engaging part arranged farther from the releasing part than the first engaging part in the first direction, and
a first protrusion amount of the first engaging part from the connecting part toward the frame wall part is larger than a second protrusion amount of the second engaging part from the connecting part toward the frame wall part.

4. The device body mounting structure according to claim 1, wherein
each of the plurality of engaging parts is arranged in parallel along the first wall part in a first direction perpendicular to a depth direction of the device body,
the plurality of engaging parts includes:
a first engaging part arranged more toward the releasing part in the first direction; and
a second engaging part arranged farther from the releasing part than the first engaging part in the first direction,
the arm part includes:
a first arm part connecting the fixing part and the first engaging part; and
a second arm part connecting the fixing part and the second engaging part, and
a length of the first arm part is shorter than that of the second arm part, or a bending rigidity of the second arm part in a second direction perpendicular to the depth direction and the first direction is lower than that of the first arm part in the second direction.
